(19) United States
(12) Patent Application Publication
(10) Pub. No.: US 2013/0258742 A1
(43) Pub. Date: Oct. 3, 2013

(54) SEMICONDUCTOR DEVICE HAVING MEMORY CELL ARRAY DIVIDED INTO PLURAL MEMORY MATS

(71) Applicant: ELPIDA MEMORY, INC., Tokyo (JP)

(72) Inventors: Hiromasa NODA, Tokyo (JP); Yasuji KOSHIKAWA, Tokyo (JP)

(21) Appl. No.: 13/905,961

(22) Filed: May 30, 2013

Related U.S. Application Data
(62) Division of application No. 12/848,443, filed on Aug. 2, 2010.

(30) Foreign Application Priority Data
Aug. 3, 2009 (JP) 2009-180990

(51) Int. Cl. G11C 5/02

(52) U.S. Cl. CPC G11C 5/02
USPC 365/51

(57) ABSTRACT

A semiconductor device includes a plurality of memory mats arranged in an X direction and a mat selecting circuit that activates a part of the memory mats based on a row address and maintains the rest of the memory mats inactivated. The memory mats are divided into a plurality of memory mat groups each including the same number of memory mats arranged in the X direction. The mat selecting circuit activates at least one of the memory mats included in each of the memory mat groups, while maintaining the rest of memory mats inactivated. With this operation, a portion of discontinuity does not occur in the memory mats arranged in the X direction, and thus the necessity of arranging two sub-word driver areas in the portion of discontinuity is eliminated.

### CROSS REFERENCE TO RELATED APPLICATIONS

This is a divisional application based upon U.S. patent application Ser. No. 12/848,443 filed Aug. 2, 2010, claiming priority based on Japanese Patent Application No. 2009-180990 filed Aug. 3, 2009, the contents of all of which are incorporated herein by reference in their entirety.

### BACKGROUND OF THE INVENTION

1. Field of the Invention

The present invention relates to a semiconductor device, and more particularly relates to a semiconductor device in which a memory cell array is divided into a plurality of memory mats.

2. Description of Related Art

Most semiconductor memory devices such as DRAM (Dynamic Random Access Memory) select a word line based on a row address supplied from outside and select a bit line based on a column address supplied from outside. However, when a large number of memory cells are allocated to one word line, a load put on the word line increases considerably. Therefore, in recent semiconductor memory devices, word lines are hierarchized in many cases. That is, there has been widely adopted a system in which one memory bank is divided into a plurality of memory mats, a memory mat is selected based on a part of a row address, and a sub-word line in the memory mat is selected based on the rest part of the row address (see Japanese Patent Application Laid-open No. H11-297962).

The memory mat is a memory cell area that is allocated to one sub-word driver area and one sense amplifier area, which is laid out in a matrix form in a word line direction (a direction in which the word line extends) and a bit line direction (a direction in which the bit line extends). That is, the memory mat has a configuration in which a plurality of rows of memory mats arranged in the word line direction are provided in the bit line direction. In a general semiconductor memory device, any one of the memory mat rows is selected based on a first part of the row address, a part (for example, a half) of the memory mats is selected from a selected memory mat row based on a second part of the row address, and any one of the sub-word line included in the selected memory mat is selected based on a third part of the row address.

Normally, a selection of the memory mats based on the second part of the row address is performed by selecting a half of the memory mats from the selected memory mat row by using an upper part of the row address.

However, selecting a half of memory mats from a selected memory mat row has problems as follows.

First, although one sub-word driver area is arranged between two memory mats adjacent to each other in the word line direction among a plurality of memory mats constituting a memory mat row, there is no case that a half of the memory mats on the right side (or the top side) and a half of the memory mats on the left side (or the bottom side) are selected at the same time. Therefore, it is required to arrange two sub-word driver areas between two memory mats arranged across their boundaries. In other words, two sub-word driver areas need to be arranged between the halves of the memory mats, while one sub-word driver area is enough between every two of the other memory mats. This is a so-called “discontinuity” in a plurality of memory mat arrays. Accordingly, this area causes an increase of the circuit size.

Second, as described above, because there is no case that a half of the memory mats on the right side (or the top side) and a half of the memory mats on the left side (or the bottom side) are selected at the same time among a plurality of memory mats constituting a memory mat row, it is required to allocate a separate I/O line to each of these memory mats. Therefore, the number of required I/O lines becomes double the number of bits input and output at a time, occupying a large portion of wiring areas. The I/O corresponds to one of the data bits that are input or output in parallel to or from a plurality of data input/output external terminals (a plurality of I/O terminals) respectively corresponding to a plurality of memory cells (each corresponding to an external address) for storing information. For example, when the I/O is 1 byte, the I/O lines are eight lines (or eight pairs for complementary signals). In practice, it is often configured with a plurality of I/O lines corresponding to an I/O terminal in a memory cell array that is constituted by a plurality of memory mats. The reason is because of a pre-fetch operation of the data bits described above.

Third, because a large number of the I/O lines are required, as described above, when the I/O lines are hierarchized into a main I/O line and a local I/O line, the number of sub-amplifiers for connecting the main I/O lines and the local I/O lines increases accordingly. Generally, the sub-amplifier is arranged at an intersection (a cross area) of a sub-word driver area in which a plurality of sub-word drivers are arranged in a bit-line extending direction in which a bit line to which memory cells are connected extends and a sense amplifier area in which a plurality of sense amplifiers are arranged in a word-line extending direction. However, because only a limited area is available for the cross area, in order to arranged a large number of the sub-amplifiers in the cross area, it is required to sacrifice the characteristics of the sub-amplifier, such as downsizing of a transistor (generally, the driving capability is degraded) or simplification of a circuit configuration (generally, the sensing sensitivity is degraded). In addition, because the number of main I/O lines MIO is large, the total number of corresponding main amplifiers increases accordingly.

The above problems occur not only in semiconductor memory devices such as DRAM, but also in any type of semiconductor devices that include a memory cell array in which a plurality of memory cells are configured with a plurality of memory mats, such as CPU (Central Processing Unit), MCU (Micro Control Unit), and DSP (Digital Signal Processor).

### SUMMARY

In one embodiment, there is provided a semiconductor device that includes a plurality of memory mats each including a plurality of memory cells; a mat selecting circuit that activates at least first to fourth memory mats that are a part of the memory mats based on a part of bits of a row address signal including a plurality of address bits that designates a row address of a memory cell, while maintaining a rest of the memory mats inactivated; a first I/O line that transfers read data read out from the activated first and second memory mats; a second I/O line that transfers read data read out from the activated third and fourth memory mats; a first main amplifier and a second main amplifier that amplify read data read out via the first and second I/O lines, respectively; and a first data input/output terminal and a second data input/output terminal that outputs the read data amplified by the first and second main amplifiers, respectively, to outside. The first and second memory mats are allocated with data corresponding to the first and second data input/output terminals, respectively. The third and fourth memory mats are allocated with data corresponding to the second and first data input/output terminals, respectively. Based on a column address signal that designates a column address of the memory cell, the first and second main amplifiers connect their outputs to the first and second data input/output terminals, respectively, when the first and third memory mats are connected to the first and second I/O lines, respectively, and connect their outputs to the second and first data input/output terminals, respectively, when the second and fourth memory mats are connected to the first and second I/O lines, respectively.

In another embodiment, there is provided a semiconductor device that includes a plurality of memory mats each including a plurality of memory cells, the memory mats being arranged in a first direction; a mat selecting circuit that activates at least first to fourth memory mats that are a part of the memory mats based on a part of bits of a row address signal that is configured with a plurality of address bits that designates a row address of a memory cell, while maintaining a rest of the memory mats inactivated; and a communication circuit that performs communication of data of the first to fourth memory mats with outside. The memory mats are divided into a plurality of memory mat groups each including a same number of memory mats arranged in the first direction. The first and second memory mats that are adjacent to each other and a part of the rest of the memory mats are included in a first memory mat group. The third and fourth memory mats that are adjacent to each other and a part of the rest of the memory mats are included in a second memory mat group. The first and third memory mats are allocated with a same first I/O data bit group and a first column address. The second and fourth memory mats are allocated with a same second I/O data bit group and a second column address. Each of memory cells of the first to fourth memory mats is allocated with a same one of the row address. The communication circuit performs communication of one of data of the first and third memory mats and data of the second and fourth memory mats with outside, without performing communication of the other one of the data with outside.

According to the present invention, because an I/O line to be used is dynamically changed based on a column address signal, it is possible to reduce the number of I/O lines. Furthermore, according to the present invention, because a plurality of memory mats arranged in a first direction are grouped into a plurality of memory mat groups and at least one memory mat included in each memory mat group is activated, a portion of discontinuity does not occur in the memory mats arranged in the first direction. Therefore, unlike conventional semiconductor memory devices, there is no need to provide two sub-word driver areas in the portion of discontinuity, and thus an increase of the circuit size can be prevented.

Further, unlike conventional semiconductor memory devices, because there is no case that a half of memory mats is exclusively selected by a row address, there is no need to allocate a separate I/O line to each of the memory mats. Therefore, the required number of I/O lines can be reduced.

Moreover, as a result of reducing the number of I/O lines, even when I/O lines are hierarchized into a main I/O line and a local I/O line, the number of sub-amplifiers for connecting the main I/O line and the local I/O line decreases accordingly. Therefore, there is no need to sacrifice the characteristics of the sub-amplifier, such as downsizing of a transistor that constitutes the sub-amplifier or simplification of a circuit configuration. In addition, because the number of main I/O lines MIO is reduced, the total number of corresponding main amplifiers can be reduced.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a block diagram of a semiconductor memory device according to an embodiment of the present invention;

FIG. 2 is a schematic diagram showing a memory mat structure of the memory cell array;

FIG. 3 is a schematic diagram for explaining a relationship between a memory mat to be activated and an address;

FIG. 4 is an enlarged diagram of an area indicated in FIG. 2;

FIG. 5 is a schematic diagram showing a detailed wiring structure of wirings connected to memory mats shown in FIG. 4;

FIG. 6 is a schematic diagram showing a wiring structure related to the row decoder and the memory mat;

FIG. 7 is a schematic diagram showing a detailed structure of memory mats shown in FIG. 4 and its peripheral circuits;

FIG. 8A is a schematic diagram for explaining a switching operation by the main amplifiers in the first state;

FIG. 8B is a schematic diagram for explaining a switching operation by the main amplifiers in the second state;

FIG. 9 is a circuit diagram of the pre-decode circuit included in the column decoder;

FIG. 10 is a circuit diagram showing a part of the main amplifier; and

FIG. 11 is a schematic diagram showing an address allocation in the semiconductor memory device according to the reference example.

### DETAILED DESCRIPTION OF THE EMBODIMENTS

A representative example of the technical concept for solving the object of the present invention is described below. Note that the claimed contents of present invention are not limited to this technical concept, and are defined by the descriptions of the appended claims. That is, the technical concept of the present invention is that a half of memory mats is not exclusively selected by a row address, memory mats to be selected are dispersed in a word-line extending direction, and a correspondence relationship between a memory mat and a data input/output terminal is dynamically switched based on a column address.

Preferred embodiments of the present invention are explained below in detail with reference to the accompanying drawings.

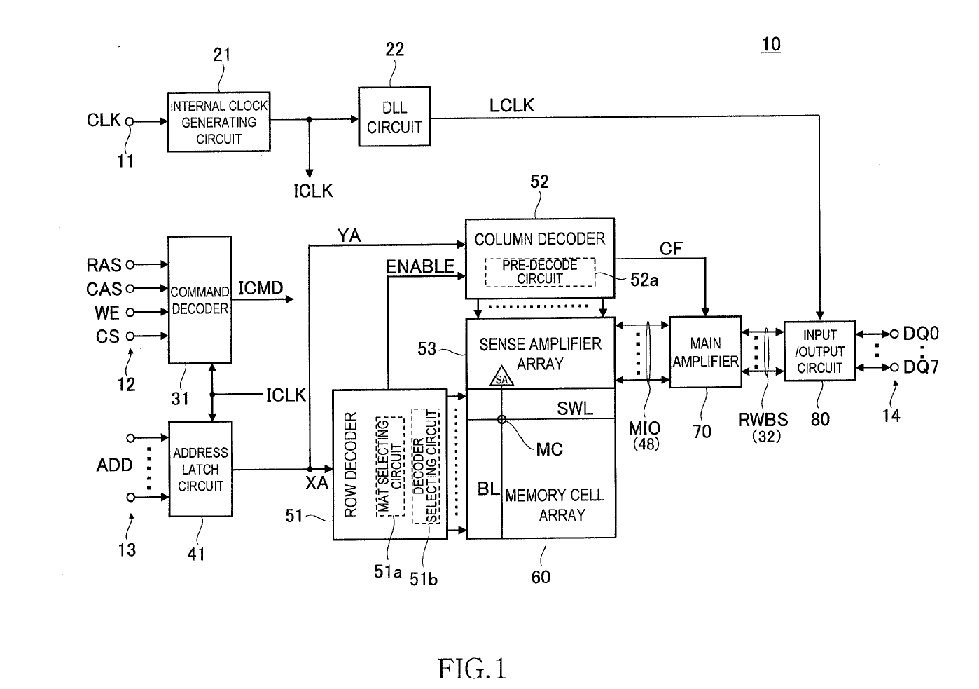

FIG. 1 is a block diagram of a semiconductor memory device 10 according to an embodiment of the present invention.

The semiconductor memory device 10 according to the present embodiment is a DDR2 (DDR stands for Double Data Rate) synchronous DRAM (Synchronous Dynamic Random Access Memory). Because the prefetch of the DDR2 synchronous DRAM is 4 bits, 4-bit data is simultaneously input and output per one I/O for a memory cell array. In addition, because the I/O of the semiconductor memory device according to the present embodiment is 8 bits, a total of 32-bit (=4×8) data is simultaneously input and output for the memory cell array.

As shown in FIG. 1, the semiconductor memory device 10 according to the present embodiment includes at least a clock terminal 11, a command terminal 12, an address terminal 13, and a data input/output terminal 14, as external terminals.

The clock terminal 11 is supplied with a clock signal CLK as a synchronization signal. The clock signal CLK is supplied to an internal clock generating circuit 21. The internal clock generating circuit 21 generates an internal clock ICLK, and supplies it to a DLL circuit 22 and various internal circuits. The DLL circuit 22 receives the internal clock ICLK and generates an output clock LCLK. The output clock LCLK is supplied to an input/output circuit 80 described later.

The command terminal 12 is supplied with command signals such as a row address strobe signal RAS, a column address strobe signal CAS, a write enable signal WE, and a chip select signal CS. These command signals are supplied to a command decoder 31. The command decoder 31 generates various internal commands ICMD by storing, decoding, and counting the command signals in synchronization with the internal clock ICLK.

The address terminal 13 is supplied with an address signal ADD. The address signal ADD is then supplied to an address latch circuit 41. The address latch circuit 41 latches the address signal ADD in synchronization with the internal clock ICLK. Among the address signals ADD that are latched in the address latch circuit 41, a row address XA is supplied to a row decoder 51, and a column address YA is supplied to a column decoder 52.

The row decoder 51 selects any one of sub-word lines SWL included in a memory cell array 60 based on the row address XA. As described later, the memory cell array 60 is divided into a plurality of memory mats. A memory mat is selected by a mat selecting circuit 51a that is included in the row decoder 51. As shown in FIG. 1, a plurality of sub-word lines SWL respectively intersect with a plurality of bit lines BL in the memory cell array 60, and a memory cell MC is arranged at every intersection of the sub-word lines SWL with the bit lines BL (However, only one sub-word line SWL, one bit line BL, and one memory cell MC are shown in FIG. 1). The bit line BL is connected to its corresponding sense amplifier SA in a sense amplifier array 53.

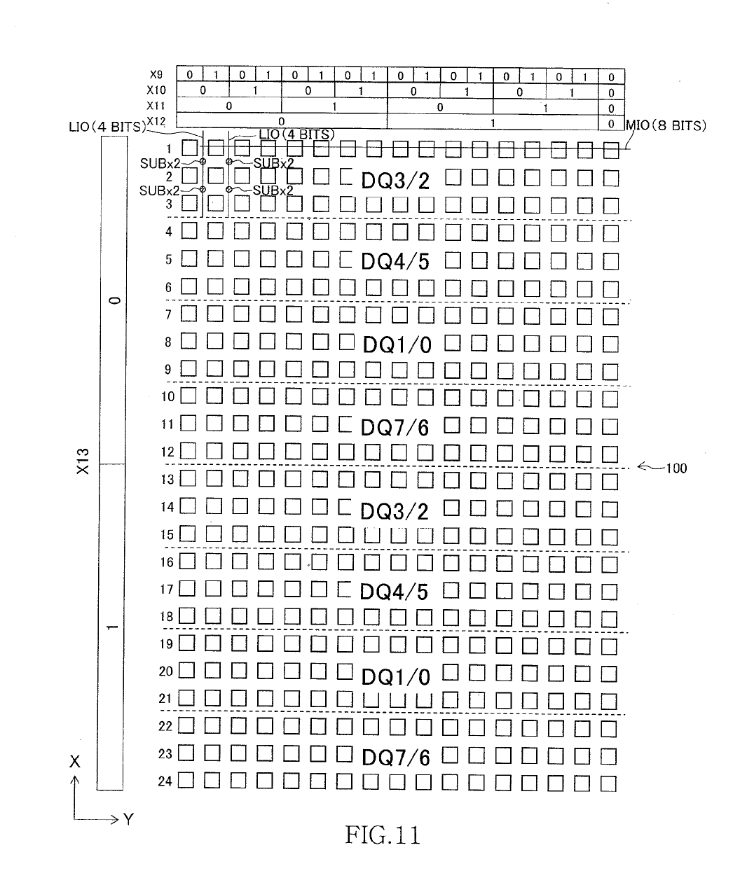

The sense amplifier SA included in the sense amplifier array 53 is selected by the column decoder 52 based on the column address YA. The selected sense amplifier SA is connected to a main amplifier 70 via a main I/O line MIO. As described above, in the semiconductor memory device 10 according to the present embodiment, because 32-bit data is simultaneously input or output to or from the memory cell array 60, the main I/O lines MIO for 32 bits are used for one input/output operation. As described later in detail, the main I/O lines MIO are provided for 48 bits in the present embodiment, and the main I/O lines MIO for 32 bits among the 48 bits are used at a time. Although it is not particularly limited, the main I/O lines MIO are formed with complementary lines in the present embodiment, so that the main I/O lines MIO are constituted by 96 (=48×2) lines. In FIG. 11 showing a comparative example described later, an attention needs to be paid to a fact that 128 (=64×2) main I/O lines MIO should be provided. Therefore, it is possible to realize the main amplifier 70 with the number of units smaller than that of the comparative example.

As described later, the column decoder 52 includes a plurality of decoders YDEC, a part of which is activated by a decoder selecting circuit 51b in the row decoder 51.

The main amplifier 70 amplifies read data that is read out from a memory cell via the main I/O lines MIO, supplies the amplified read data to the read/write bus RWBS, and supplies write data supplied from outside via the read/write bus RWBS to the main I/O lines MIO. The read/write bus RWBS is a single-end type wiring, so that 32 lines are provided therefor. One of the characteristics of the present invention is that a correspondence relationship between the main I/O line MIO and the read/write bus RWBS is not fixed, but is switched based on a pre-decode signal CF (a signal that is obtained by partially decoding a portion of the column address) that is supplied from the column decoder 52. A portion of the column address indicates a portion of address bits constituting the column address. In the following explanations, a portion of address bits constituting a row address (or a column address) may be simply referred to as “portion of address”.

The read/write bus RWBS is connected to the input/output circuit 80. The input/output circuit 80 performs a parallel-to-serial conversion and a serial-to-parallel conversion for responding to the clock signal CLK having a high frequency. With the input/output circuit 80, the read data that is read out in parallel via the read/write bus RWBS is output in series via the data input/output terminal 14, and the write data that is input in series via the data input/output terminal 14 is supplied to the read/write bus RWBS in parallel. To explain it in detail with a read operation as an example, the read data supplied in parallel via 32 lines of the read/write bus RWBS is converted into 4-bit serial data for each I/O, and 4-bit read data is output from each of eight data input/output terminals 14 in synchronization with the output clock LCLK.

The overall configuration of the semiconductor memory device 10 according to the present embodiment is as described above. An operation of the semiconductor memory device 10 according to the present embodiment is explained below in detail with focusing on the memory cell array 60.

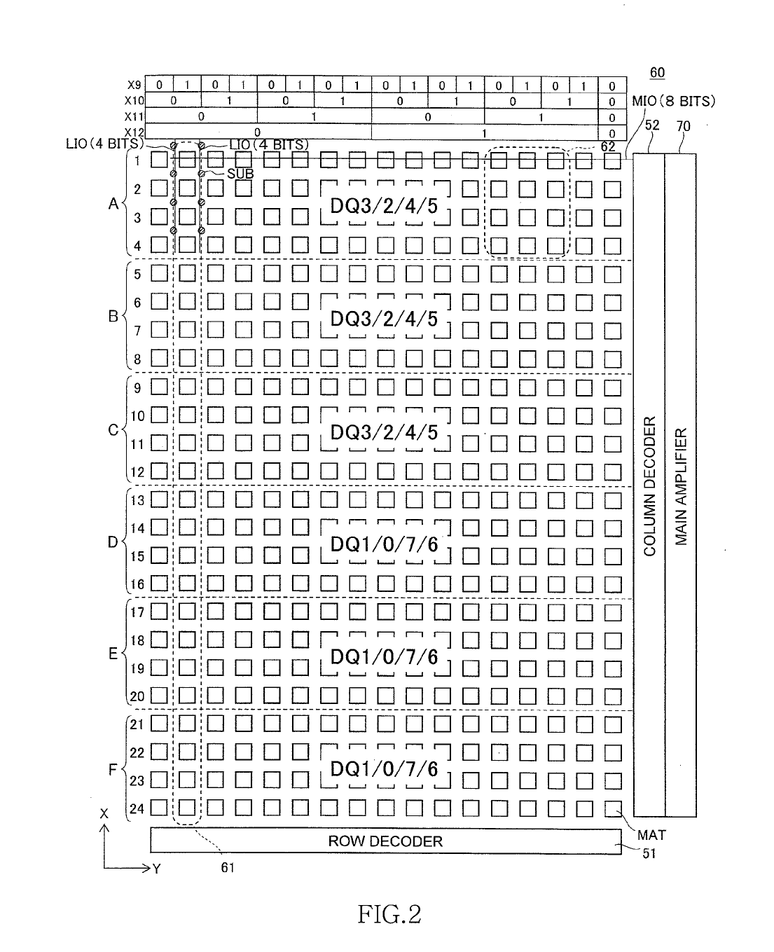

FIG. 2 is a schematic diagram showing a memory mat structure of the memory cell array 60.

As shown in FIG. 2, the present embodiment has a matrix structure in which 24 mats of a memory mat MAT are arranged in an X direction (the word-line extending direction) and 17 mats of the memory mat MAT are arranged in the bit-line extending direction (a Y direction). In other words, 17 rows of 24 memory mat column are arranged in the X direction. A memory mat row is selected based on a portion of the row address XA, X9 to X12, as shown in FIG. 2. For example, when X9 to X12 is “1000”, a memory mat row 61 at the second row is selected. The memory mat row is selected by the mat selecting circuit 51a.

The reason why the 17 mats are arranged in the bit-line extending direction (the Y direction) is because the memory cell array shown in FIG. 2 is the open-bit-line structure memory array described in Japanese Patent Application No. 2008-203747. When X9 to X12 is “0000”, the rows at the edges, memory mat rows 61 at the first row and the seventeenth row are selected. However, the technical concept of the present invention can be also applied to a folded bit-line structure.

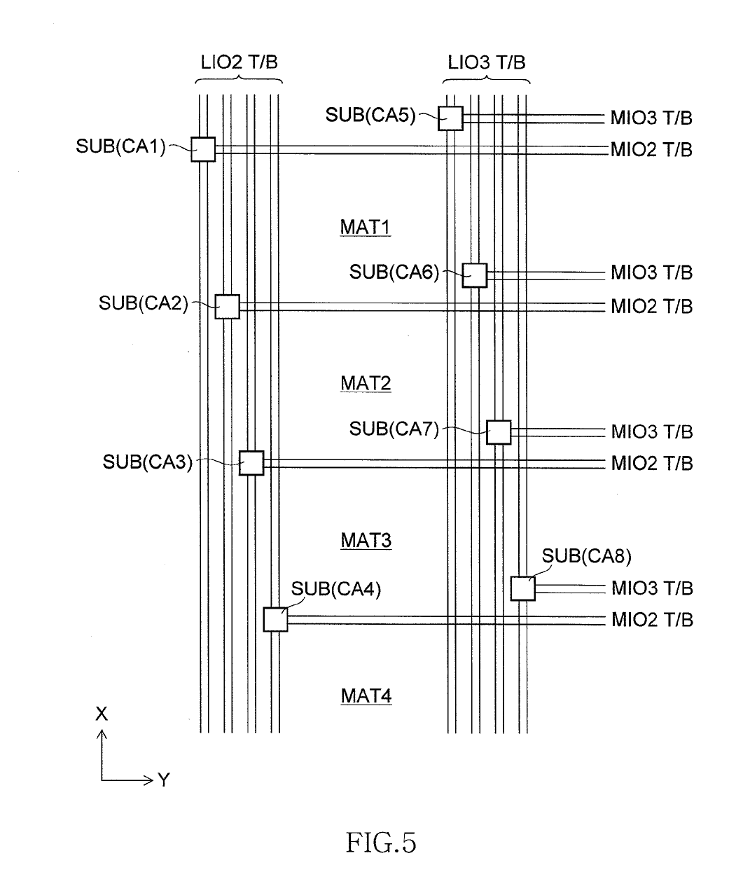

In the present embodiment, 24 memory mats that constitute each memory mat row are divided into six groups A to F by four columns. Each of the memory mat groups is a unit that shares a local I/O line LIO and a main I/O line MIO. The local I/O line LIO is a wiring that extends in the X direction, which is used for connecting a sense amplifier that is associated with each memory mat and the main I/O line MIO. On the other hand, the main I/O line MIO is a wiring that extends in the Y direction, which is used for connecting the local I/O line LIO and the main amplifier 70. The local I/O line LIO and the main I/O line MIO is connected via a sub-amplifier SUB that is arranged at a cross area CA. Details on this aspect are explained with reference to FIG. 5.

In the present embodiment, eight pairs of the main I/O lines MIO are allocated to one memory mat group (constituted by four columns of memory mats). Therefore, the total of 48 pairs (8×6 pairs) of main I/O lines MIO is provided. As described above, the main I/O lines MIO that are used at a time is 32 pairs among the 48 pairs, and the main I/O lines MIO to be used are determined based on portions of the row address XA and the column address YA. Details on this aspect are described later.

Among the four memory mats that constitute each of the memory mat groups, two memory mats are activated based on a portion of the row address XA (X13), while the other two memory mats are remained inactivated. The activation of the memory mat indicates a state that any one of the sub-word lines SWL is activated so that a corresponding memory cell is accessed. In this manner, in the present embodiment, two memory mats are activated in one memory mat group, which is repeated in a plurality of memory mat groups (A to F), so that positions of memory mats to be activated are dispersed in the X direction.

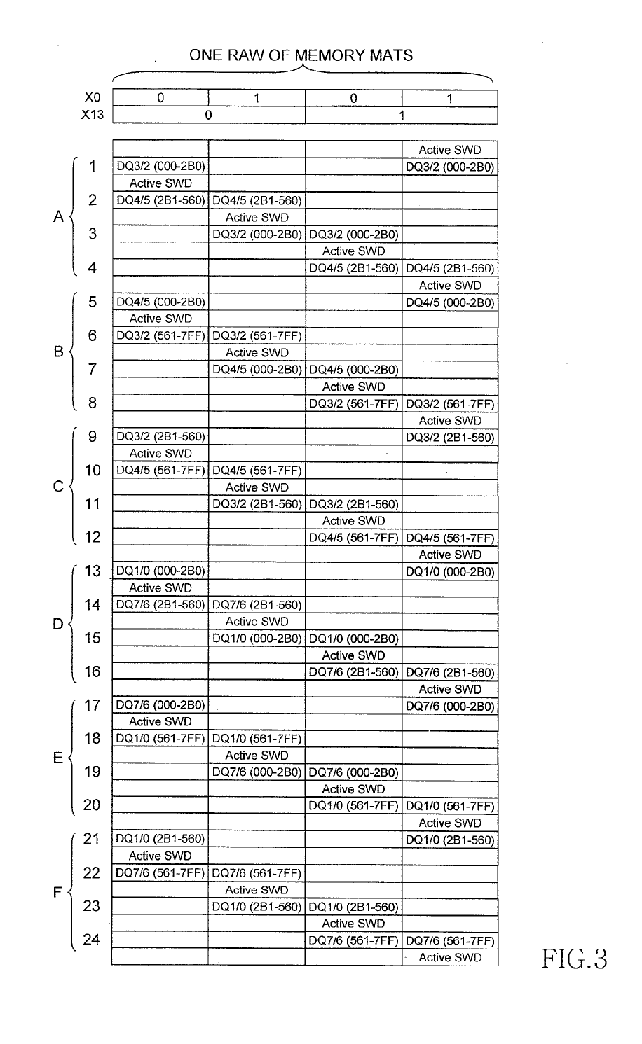

FIG. 3 is a schematic diagram for explaining a relationship between a memory mat to be activated and an address. An attention should be paid to a fact that it is represented with four rows how the 24 memory mat columns included in one memory mat row shown in FIG. 2 are selected by X0 and X13, which are a portion of the row address XA, without meaning a physical structure.

The numbers 1 to 24 at the left side of the table shown in FIG. 3 indicate column numbers of the memory mats, and contents described in the right-side fields (inside a frame that indicates the memory mat) are numbers (DQ numbers) of the data input/output terminal 14 that are connection destinations and column address ranges at the time of selection. For example, when both X0 and X13, which are a portion of the row address XA, are “0”, memory mats at the first, the second, the fifth, the sixth, the ninth, the tenth, the thirteenth, the fourteenth, the seventeenth, the eighteenth, the twenty-first, and the twenty-second columns are selected. Similarly, when X0 and X13 are “1” and “0”, respectively, the second, the third, the sixth, the seventh, the tenth, the eleventh, the fourteenth, the fifteenth, the eighteenth, the nineteenth, the twenty-second, and the twenty-third columns are selected. When X0 and X13 are “0” and “1”, respectively, the third, the fourth, the seventh, the eighth, the eleventh, the twelfth, the fifteenth, the sixteenth, the nineteenth, the twentieth, the twenty-third, and the twenty-fourth columns are selected. When both X0 and X13 are “1”, the first, the fourth, the fifth, the eighth, the ninth, the twelfth, the thirteenth, the sixteenth, the seventeenth, the twentieth, the twenty-first, and the twenty-fourth columns are selected. The columns is selected by the mat selecting circuit 51a shown in FIG. 1.

Furthermore, among the selected 12 memory mats, sense amplifiers respectively associated with four memory mats according to the column address are actually connected to the main I/O line MIO. Specifically, in the case that both X0 and X13 are “0”, when the column address is in a range of 000 to 2B0, the memory mats at the first, the fifth, the thirteenth, and the seventeenth columns are connected to the main I/O line MIO, when the column address is in a range of 2B1 to 560, the memory mats at the second, the ninth, the fourteenth, and the twenty-first columns are connected to the main I/O line MIO, and when the column address is in a range of 561 to 7FF, the memory mats at the sixth, the tenth, the eighteenth, and the twenty-second columns are connected to the main I/O line MIO. Memory mats that are not connected to the main I/O line MIO perform a so-called “refresh” of data stored in a memory cell by a sense amplifier. The refresh is a data maintaining operation by recharging electrical charges that indicate data stored in the memory cell.

As described above, in the case that the memory mats at the first, the fifth, the thirteenth, and the seventeenth columns are connected to the main I/O lines MIO, main I/O lines MIO respectively allocated to groups A, B, D, and E are used. That is, these main I/O lines MIO are targets to be accessed, so that outside and the memory cell are in a communicating state. On the other hand, main I/O lines MIO allocated to groups C and F are not used. That is, these main I/O lines MIO are out of targets to be accessed, which are controlled to, for example, a predetermined equalizing potential. At this time, the selected groups A, B, D, and E are allocated to DQ3/2, DQ4/5, DQ1/0, and DQ7/6, respectively.

Similarly, in the case that the memory mats at the second, the ninth, the fourteenth, and the twenty-first columns are connected to the main I/O lines MIO, main I/O lines MIO respectively allocated to groups A, C, D, and F are used, while main I/O lines MIO allocated to groups B and E are not used. At this time, the selected groups A, C, D, and Fare allocated to DQ4/5, DQ3/2, DQ7/6, and DQ1/0, respectively. Furthermore, in a case that the memory mats at the sixth, the tenth, the eighteenth, and the twenty-second columns are connected to the main I/O lines MIO, main I/O lines MIO respectively allocated to groups B, C, E, and F are used, while main I/O lines MIO allocated to groups A and D are not used. At this time, the selected groups B, C, E, and F are allocated to DQ3/2, DQ4/5, DQ1/0, and DQ7/6, respectively.

In this manner, the main I/O lines MIO to be used are not fixed in terms of communicating data bits corresponding to a memory cell to which a specific I/O is assigned, but is dynamically changed according to the row address XA and the column address YA. Furthermore, a correspondence relationship between the main I/O line MIO and the data input/output terminal 14 is also dynamically changed according to the row address XA and the column address YA.

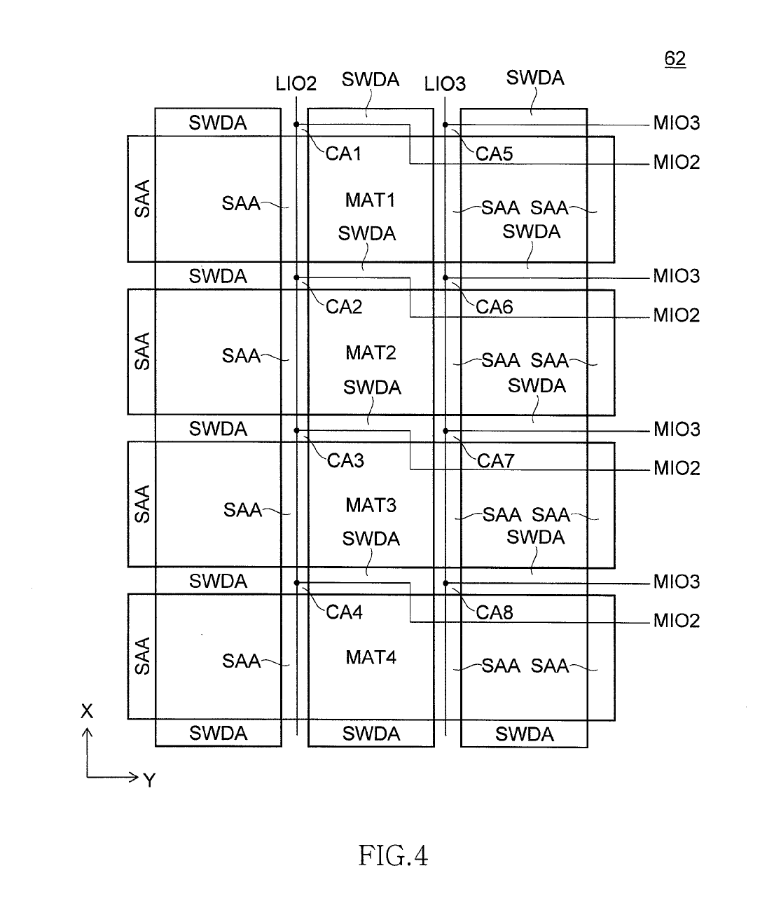

FIG. 4 is an enlarged diagram of an area 62 shown in FIG. 2, and FIG. 5 is a schematic diagram showing a detailed wiring structure of wirings connected to memory mats MAT1 to MAT4 shown in FIG. 4.

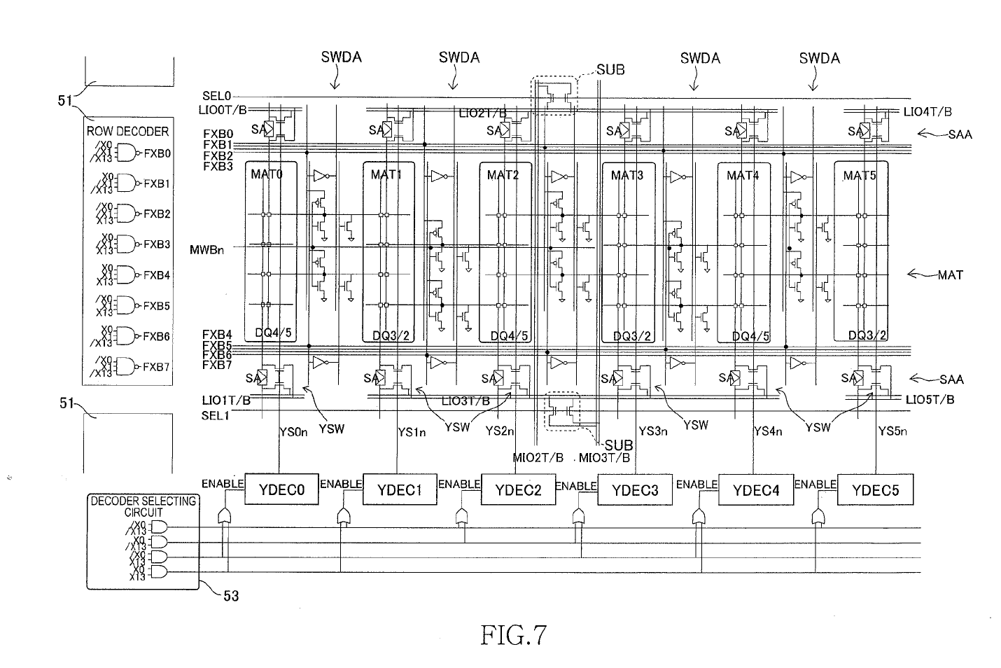

As shown in FIG. 4, a sub-word driver area SWDA is arranged between two memory mats MAT that are adjacent to each other in the X direction, and a sense amplifier area SAA is arranged between two memory mats MAT that are adjacent to each other in the Y direction. The sub-word driver area SWDA includes a plurality of sub-word drivers. When a predetermined sub-word driver area SWDA is selected, memory mats at both sides of the sub-word driver area SWDA adjacent to each other in the X direction are activated. The sense amplifier area SAA includes a plurality of sense amplifiers SA. A part of the sense amplifiers SA is connected to the local I/O line LIO by the column decoder 52 (see FIG. 1). An example of its connection structure (column switch YSW) is shown in FIG. 7.

In FIG. 4, memory mats MAT1 to MAT4 belong to the same group A. A local I/O line LIO2 is formed on the sense amplifier area SAA that is located at the left side of the memory mats MAT1 to MAT4, and a local I/O line LIO3 is formed on the sense amplifier area SAA that is located at the right side of the memory mats MAT1 to MAT4. Although four pairs (=eight lines) are arranged for each of the local I/O lines LIO2 and LIO3 to simultaneously input and output 4-bit data in practice, as shown in FIG. 5, one line is representatively shown in FIG. 4 for the sake of simplicity.

The local I/O line LIO and the main I/O line MIO is connected via the sub-amplifier SUB that is arranged in a cross area CA. The cross area CA is located at the intersection of the sub-word driver area SWDA that extends in the Y direction with the sense amplifier area SAA that extends in the X direction. Because the dimension of the cross area CA is determined by a width of the sub-word driver area SWDA in the X direction and a width of the sense amplifier area SAA in the Y direction, only a considerably limited area is available for the cross area CA.

In the present embodiment, eight cross areas CA1 to CA8 are allocated to the four memory mats MAT1 to MAT4 that constitute one group. The main I/O lines MIO allocated to one group are eight pairs as described above. Therefore, as shown in FIGS. 4 and 5, by arranging one sub-amplifier SUB (shown in FIG. 7) in each of the eight cross areas CA1 to CA8, it is possible to accommodate all sub-amplifiers SUB. The sub-amplifier SUB is a so-called “transfer gate (switch)” that connected the local I/O line LIO and the main I/O line MIO with a source and a drain. As a substitute for the transfer gate, a transistor of an amplifying circuit type can be used. In this case, as can be understood from FIG. 5, it is possible to realize a sub-amplifier with a high driving capability, because one sub-amplifier can be arranged in one cross area CA with a small dimension. In other words, one local I/O line LIO is shared by a plurality of memory mats to which different DQs are assigned from each other, data bits of different DQs according to the address are transferred to the local I/O line LIO, and a sub-amplifier with a high driving capability can be realized, which connects the local I/O line LIO and the main I/O line MIO at any one of the cross areas CA.

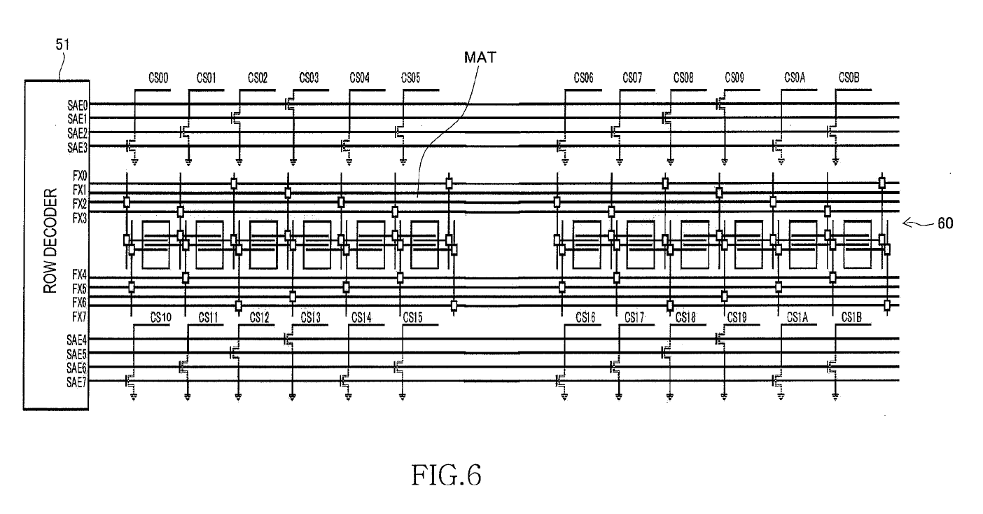

FIG. 6 is a wiring diagram showing a relationship between the row decoder 51 and the memory mat MAT, and FIG. 7 is a detailed schematic diagram showing a structure of the memory mats MAT1 to MAT4 shown in FIG. 4 and peripheral circuits thereof.

As shown in FIG. 6, the row decoder 51 is arranged at an edge of the memory cell array 60 in the X direction, and generates sense amplifier enable signals SAE0 to SAE7 and sub-word line select signals FX0 to FX7. The row decoder 51 further generates a main word line select signal MWBn (see FIG. 7), which is not shown in FIG. 6. One memory mat row is shown in FIG. 6. As shown in FIG. 7, the sub-word line select signals FX0 to FX7 are generated from a logical product of X0, X1, and X13 that are a part of the row address XA. Therefore, four lines of signals (for example, FX0 to FX3) are allocated per single sense amplifier area SAA. The sense amplifier SA needs to be activated in response to the sub-word line select signal FX, and therefore the sense amplifier enable signals SAE become four lines (for example, SAE0 to SAE3) per single sense amplifier area SAA. Furthermore, a common source of the sense amplifier SA also needs to be separated for each memory mat (CS00 to CS0B, CS10 to CS1B). Because the sense amplifiers SA are simultaneously activated in the word-line extending direction (the X direction), a power supply line needs to have a low resistance in a direction perpendicular to the sense amplifier array. Therefore, there is little influence by an increase of wiring channels of the sense amplifier enable signals SAE.

As shown in FIG. 7, a column decoder YDEC is allocated to each corresponding sense amplifier area SAA. The column decoder YDEC constitutes a part of the column decoder 52 shown in FIG. 1. Although not shown in FIG. 7, a pre-decode signal CF is input to each corresponding column decoder YDEC, based on which a part of the sense amplifiers SA in a corresponding sense amplifier area SAA is connected to the local I/O line LIO. In FIG. 7, local I/O lines LIO and their related circuits corresponding to two main I/O lines MIO (MIO2T/B and MIO3T/B) are only shown, to represent the peripheral circuits in a simple manner. In practice, eight pairs of main I/O lines MIO are provided for four memory mats MAT.

Further, the memory mats are sequentially numbered from zero. One memory mat includes a plurality of memory cells respectively corresponding to a plurality of DQs. For example, in the memory mat MAT1, a second memory cell corresponding to DQ2 is connected to a second bit line, the second bit line is connected to a second sense amplifier SA, the second sense amplifier SA is connected to a second local bit line (LIO2T/B) via a column switch YSW, and the second local bit line is connected to a second main I/O line (MIO2T/B) via a sub-amplifier. A third memory cell corresponding to DQ3 is connected to a third bit line, the third bit line is connected to a third sense amplifier SA, the third sense amplifier SA is connected to a third local bit line (LIO3T/B) via a column switch YSW, and the third local bit line is connected to a third main I/O line (MIO3T/B) via a sub-amplifier.

Meanwhile, in the memory mat MAT2, a second memory cell corresponding to DQ4 is connected to the second bit line, the second bit line is connected to the second sense amplifier SA, the second sense amplifier SA is connected to the second local bit line (LIO2T/B) via a column switch YSW, and the second local bit line is connected to the second main I/O line (MIO2T/B) via a sub-amplifier. A third memory cell corresponding to DQ5 is connected to the third bit line, the third bit line is connected to the third sense amplifier SA, the third sense amplifier SA is connected to the third local bit line (LIO3T/B) via a column switch YSW, and the third local bit line is connected to the third main I/O line (MIO3T/B) via a sub-amplifier.

The column decoder YDEC is activated based on an enable signal ENABLE that is generated by the decoder selecting circuit 51b (shown in FIG. 1). The decoder selecting circuit 51b generates the enable signal ENABLE based on X0 and X13 that are a portion of the row address XA. As is clear from the circuit shown in FIG. 7, the decoder selecting circuit 51b activates two column decoders among four column decoders YDEC that are allocated to one group, based on logical levels of X0 and X13, while maintaining the rest two of the column decoders inactivated. For example, when both X0 and X13 are “0”, column decoders YDEC1 and YDEC2 are activated, and column decoders YDEC3 and YDEC4 are remained inactivated.

However, column select signal YS output from the four column decoders YDEC that are allocated to the same group are input to the column switches YSW that are connected to the same local I/O line LIO. Therefore, a column select signal YS output from either one of the two activated column decoders YDEC is only activated. It is because address allocations of the column decoders YDEC1 and YDEC2 are different from each other, as shown in FIG. 2 (different column addresses are allocated to memory mats at both sides facing each other across a sub-word driver SWD).

With this configuration, only a sense amplifier area SAA allocated to any one of the four memory mats MAT1 to MAT4 that belong to the same group becomes connected to the local I/O line LIO via the column switch YSW. Therefore, because the local I/O line LIO is connected to the main I/O line MIO via the sub-amplifier SUB, a total of 32 sense amplifiers SA are connected to the main amplifiers 70 via 32 pairs of main I/O lines MIO. As a result, one local I/O line LIO shared by one memory mat group (constituted by four columns of memory mats) and one related main I/O line MIO are assigned with either one of DQ2 (or DQ3) and DQ4 (or DQ5) by the column decoder YDEC that is controlled based on X0, X13, and the column address. Because there are eight lines of the main I/O line MIO per single memory mat group (four lines of the main I/O line MIO per single DQ), it is possible to realize 4-bit prefetch data. The DQ to be connected to one main I/O line MIO is determined by the address.

In FIG. 7, the sense amplifier is the open-bit-line structure, in which, for example, the memory mat MAT1 is an access side bit line from the sense amplifier, and a memory mat (a neighboring memory mat row, not shown) facing the memory mat MAT1 across the sense amplifier is a reference side bit line. Furthermore, it is a skewered bit line structure in which a plurality of access side bit lines adjacent to each other in a memory mat and a plurality of reference side bit lines adjacent to each other are alternately connected with a plurality of sense amplifiers arranged at both edges of the memory mat in a direction of the memory mat row (the Y direction).

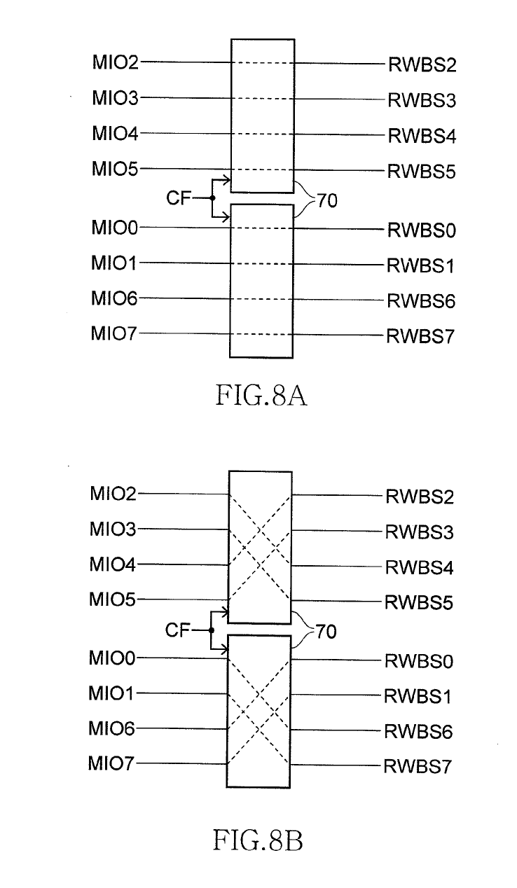

FIGS. 8A and 8B are schematic diagrams for explaining a switching operation by the main amplifier 70.

As shown in FIGS. 8A and 8B, a pre-decode signal CF that is obtained by partially decoding a portion of the column address YA is input to the main amplifier 70, by which a connection relationship between main I/O lines MIO0 to MIO7 and read/write buses RWBS0 to RWBS7 is switched. Specifically, as shown in FIG. 8A, in a first state, the main I/O lines MIO0 to MIO7 correspond to the read/write buses RWBS0 to RWBS7 as they are, respectively. On the other hand, as shown in FIG. 8B, in a second state, the main I/O lines MIO0 to MIO7 correspond to the read/write buses RWBS6, RWBS7, RWBS4, RWBS5, RWBS2, RWBS3, RWBS0, and RWBS1, respectively. The read/write buses RWBS0 to RWBS7 correspond to DQ0 to DQ7 of the data input/output terminal 14, respectively, with a fixed connection relationship.

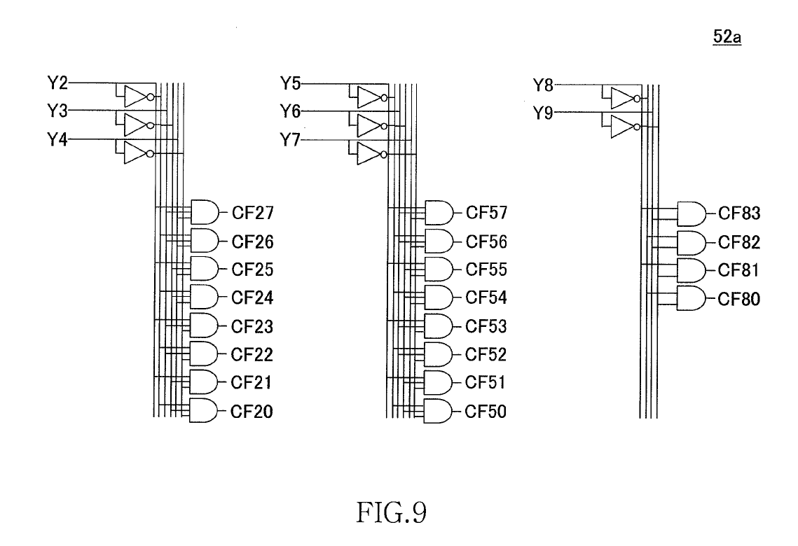

FIG. 9 is a circuit diagram of a pre-decode circuit 52a included in the column decoder 52.

The pre-decode circuit 52a shown in FIG. 9 generates pre-decode signals CF20 to CF27 by decoding Y2 to Y4 of the column address YA, generates pre-decode signals CF50 to CF57 by decoding Y5 to Y7, and generates pre-decode signals CF80 to CF83 by decoding Y8 and Y9. The pre-decode signals generated in the above manner are supplied to the column decoder YDEC shown in FIG. 7 and the main amplifier 70 shown in FIGS. 8A and 8B.

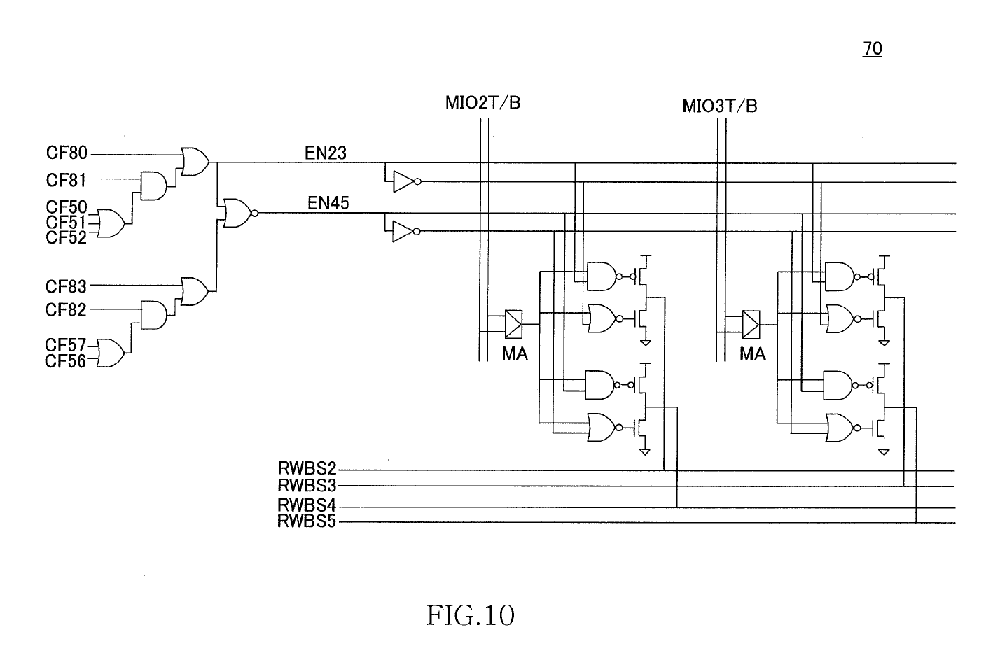

FIG. 10 is a circuit diagram of a part of the main amplifier 70.

The part shown in FIG. 10 performs a switching between a first connection in which the main I/O lines MIO2 and MIO3 are respectively connected to the read/write buses RWBS2 and RWBS3 and a second connection in which the main I/O lines MIO2 and MIO3 are respectively connected to the read/write buses RWBS4 and RWBS5. As shown in FIG. 10, the pre-decode signals CF50 to CF52, CF56, CF57, and CF80 to CF83 are decoded by a control circuit 71, and the switching between the connections is performed based on enable signals EN23 and EN45 that are generated from the pre-decode signals. Specifically, when a logical value of the enable signal EN23 is a high level, the main I/O lines MIO2 and MIO3 are connected to the read/write buses RWBS2 and RWBS3, respectively, and when a logical value of the enable signal EN45 is a high level, the main I/O lines MIO2 and MIO3 are connected to the read/write buses RWBS4 and RWBS5, respectively.

As described above, according to the present embodiment, because a plurality of memory mats MAT arranged in the X direction are divided into a plurality of memory mat groups A to F, and two memory mats included in each of the memory mat groups are activated, a portion of discontinuity (the problem of discontinuity described in the description of the related art) does not occur in the memory mats arranged in the X direction. Therefore, it is possible to make all sub-word driver areas arranged between the memory mats have the same circuit configuration. It means that two sub-word driver areas SWDA arranged between a plurality of memory mats MAT are not necessary, the plurality of memory mats are arranged in the X direction corresponding to a place where X13 varies in a reference example described later. As a result, it is possible to reduce the chip dimension.

Furthermore, in the present embodiment, because the main I/O line MIO to be used is dynamically changed based on the row address XA and the column address YA, it is possible to reduce the number of main I/O lines MIO.

Moreover, because the number of main I/O lines MIO is reduced, the number of the sub-amplifiers SUB for connecting the main I/O line MIO and the local I/O line LIO is reduced accordingly, so that it is only necessary to arrange one sub-amplifier SUB in each cross area CA. Therefore, there is no need to sacrifice the characteristics of the sub-amplifier SUB, such as downsizing of a transistor that constitutes the sub-amplifier SUB or simplification of a circuit configuration. Further, because the number of main I/O lines MIO is reduced, the total number of corresponding main amplifiers can be reduced accordingly.

FIG. 11 is a schematic diagram showing an address allocation in a semiconductor memory device as a reference example (associated diagram) in which the inventors of the present invention derived a further problem from Patent Document 1 to support the characteristics and advantages of the present invention. FIG. 11 corresponds to FIG. 2.

In the reference example shown in FIG. 11, an upper half of the memory mats or the lower half of the memory mats is selected based on X13. In this address allocation, because there is no case that the upper half of the memory mats and the lower half of the memory mats are simultaneously selected, it is required to arrange two sub-word driver areas at a position 100, which is a boundary between them. For this reason, this area causes an increase of the circuit size.

Furthermore, unlike the present invention, because there is no case that the upper half of the memory mats and the lower half of the memory mats are simultaneously selected, it is required to allocate separate main I/O lines MIO to those memory mats. Specifically, with three memory mats arranged in the X direction as one group, the main I/O line MIO is allocated to the group in a fixed manner. Therefore, the main I/O line MIO is separately needed for each of the upper half of the memory mats and the lower half of the memory mats, and as a result, a total of 64 pairs (=128 lines) of main I/O lines MIO should be formed.

Furthermore, although each group requires eight sub-amplifiers, because there are only six cross areas CA in one group in the layout shown in FIG. 11, it is necessary to arrange two sub-amplifiers SUB in one cross area CA in consideration of the symmetry. As described above, because only a limited area is available for the cross area CA, it is required to sacrifice the characteristics of the sub-amplifier SUB, such as downsizing of a transistor that constitutes the sub-amplifier SUB or simplification of a circuit configuration, to arrange two sub-amplifiers in one cross area CA. In addition, because there are a large number of main I/O lines MIO, the total number of corresponding main amplifiers becomes large accordingly.

All of these problems can be solved by the semiconductor memory device 10 in this embodiment of the present invention.

It is apparent that the present invention is not limited to the above embodiments, but may be modified and changed without departing from the scope and spirit of the invention.

For example, although a DRAM has been considered in the above embodiment, the basic technical concept of the present invention is not limited to a DRAM, and can be applied to any synchronous memories, such as an SRAM or a nonvolatile memory. Further, the circuit configurations of the sub-word driver, the sense amplifier, the main amplifier, the column switch, and the sub-amplifier are not limited particular configurations. In addition, voltages of various signal lines are not limited to particular values.

For example, although a read operation of reading out data to be output to outside from a memory cell is partially described in the above embodiment using the main amplifier 70 and the sub-amplifier SUB, the same concept can be realized for a write operation of writing external data input from outside in a memory cell using a write amplifier. Those skilled in the art can easily understand this aspect. That is, in the explanations of the present invention, the local I/O line LIO, the main I/O line MIO, and the read/write bus RWBS are bidirectional signal lines in data communication, so that the technical concept of the present invention can be applied to a read only operation, a write only operation, and both the read and write operations. In a case of an interface for a two-port memory and the like, the case of the read only operation or the write only operation can be applied.

The present invention can be also applied to semiconductor devices such as SOC (System on Chip), MCP (Multi Chip Package), and POP (Package on Package). Furthermore, the present invention can be also applied to semiconductor devices including memory cells and having a logical function, as well as other semiconductor devices such as CPU, MCU, and DSP.

When an FET (Field Effect Transistor) is used as the transistor in the present invention, various types of FETs such as MIS (Metal-Insulator Semiconductor) and TFT (Thin Film Transistor) can be used as well as MOS (Metal Oxide Semiconductor). As the transistor, other than FETS, various types of transistors such as a bipolar transistor can be also used.

In addition, an NMOS transistor (N-channel MOS transistor) is a representative example of a first conductive transistor, and a PMOS transistor (P-channel MOS transistor) is a representative example of a second conductive transistor.

Many combinations and selections of various constituent elements disclosed in this specification can be made within the scope of the appended claims of the present invention. That is, it is needles to mention that the present invention embraces the entire disclosure of this specification including the claims, as well as various changes and modifications which can be made by those skilled in the art based on the technical concept of the invention.

What is claimed is:

1. A semiconductor device comprising:
first, second, third, fourth, fifth, sixth, seventh and eighth memory mats that are arranged in line in that order, each of the first to eighth memory mats including a plurality of memory cells; and
a selection circuit that is configured to respond to a first bit of a row address including a plurality of bits and to activate the first, second, fifth and sixth memory mats in parallel to one another with deactivating the third, fourth, seventh and eighth memory mats when the first bit of the row address is one of logic-1 and logic-0 and to activate the third, fourth, seventh and eighth memory mats in parallel to one another with deactivating the first, second, fifth and sixth memory mats when the first bit of the row address is the other of logic-1 and logic-0.

2. The device as claimed in claim 1,
wherein each of the first to eighth memory mats further includes a plurality of word lines; and
wherein the device further comprises first, second, third and fourth word drivers, the first word driver being between the first and second memory mats to be connected to the word lines of each of the first and second memory mats, the second word driver being between the third and fourth memory mats to be connected to the word lines of each of the third and fourth memory mats, the third word driver being between the fifth and sixth memory mats to be connected to the word lines of each of the fifth and sixth memory mats, and the fourth word driver being between the seventh and eighth memory mats to be connected to the word lines of each of the seventh and eighth memory mats.

3. The device as claimed in claim 2, further comprising first and second data terminals, the first, third, sixth and eighth memory mats being allocated to the first data terminal and the second, fourth, fifth and seventh memory mats being allocated to the second data terminal.

4. The device as claimed in claim 3, wherein one of the first and sixth memory mats and one of the second and fifth memory mats, that are selected in response to a column address, are connected electrically to the first and second data terminals, respectively, when the first bit of the row address is the one of logic-1 and logic-0, and one of the third and eighth memory mats and one of the fourth and seventh memory mats, that are selected in response to the column address, are connected electrically to the first and second data terminals, respectively, when the first bit of the row address is the other of logic-1 and logic-0.

5. The device as claimed in claim 1, wherein the selection circuit is further configured to respond to a second bit of the row address and to activate the first, second, fifth and sixth memory mats in parallel to one another with deactivating the third, fourth, seventh and eighth memory mats when each of the first and second bits of the row address is the one of logic-1 and logic-0, to activate the third, fourth, seventh and eighth memory mats in parallel to one another with deactivating the first, second, fifth and sixth memory mats when the first bit of the row address is the other of logic-1 and logic-0 and the second bit of the row address is the one of logic-1 and logic-0, to activate the second, third, sixth and seventh memory mats In parallel to one another with deactivating the first, fourth, fifth and eighth memory mats when the first bit of the row address is the one of logic-1 and logic-0 and the second bit of the row address is the other of logic-1 and logic-0, and to activate the first, fourth, fifth and eighth memory mats in parallel to one another with deactivating the second, third, sixth and seventh memory mats when each of the first and second bits of the row address is the other of logic-1 and logic-0.

6. The device as claimed in claim 5, wherein the first bit of the row address is the most significant bit and the second bit of the row address is the least significant bit.

7. The device as claimed in claim 5,
wherein each of the first to eighth memory mats further includes a first set of word lines and a second set of word lines; and
wherein the device further comprises first, second, third, fourth, fifth, sixth, seventh, eighth and ninth word drivers, the first word driver being connected to the first set of word lines of the first memory mat, the second word driver being between the first and second memory mats to be connected to the second set of word lines of the first memory mat and to the first set of word lines of the second memory mat, the third word driver being between the second and third memory mats to be connected to the second set of word lines of the second memory mat and to the first set of word lines of the third memory mat, the fourth word deriver being between the third and fourth memory mats to be connected to the second set of word lines of the third memory mat and to the first set of word lines of the fourth memory mat, the fifth word deriver being between the fourth and fifth memory mats to be connected to the second set of word lines of the fourth memory mat and to the first set of word lines of the fifth memory mat, the sixth word deriver being between the fifth and sixth memory mats to be connected to the second set of word lines of the fifth memory mat and to the first set of word lines of the sixth memory mat, the seventh word driver being between the sixth and seventh memory mats to be connected to second set of word lines of the sixth memory mat and to the first set of word lines of the seventh memory mat, the eighth word driver being between the seventh and eighth memory mats to be connected to the second set of word lines of the seventh memory mat and the first set of word lines of the eighth memory mats, and the ninth word driver being connected to the second set of word lines of the eighth memory mat.

8. The device as claimed in claim 7, further comprising first and second data terminals, the first, third, sixth and eighth memory mats being allocated to the first data terminal and the second, fourth, fifth and seventh memory mats being allocated to the second data terminal.

9. The device as claimed in claim 8, wherein
one of the first and sixth memory mats and one of the second and fifth memory mats, that are selected in response to a column address, are connected electrically to the first and second data terminals, respectively, when each of the first and second bits of the row address is the one of logic-1 and logic-0,
one of the third and eighth memory mats and one of the fourth and seventh memory mats, that are selected in response to the column address, are connected electrically to the first and second data terminals, respectively, when the first bit of the row address is the other of logic-1 and logic-0 and the second bit of the row address is the one of logic-1 and logic-0,
one of the third and sixth memory mats and one of the second and seventh memory mats, that are selected in response to the column address, are connected electrically to the first and second data terminals, respectively, when the first bit of the row address is the one of logic-1 and logic-0 and the second bit of the row address is the other of logic-1 and logic-0, and
one of the first and eighth memory mats and one of the fourth and fifth memory mats, that are selected in response to the column address, are connected electrically to the first and second data terminals, respectively, when each of the first and second bits of the row address is the other of logic-1 and logic-0.

10. The device as claimed in claim 9, wherein the first bit of the row address is a more significant bit and the second bit of the row address is a less significant bit.

11. A semiconductor device comprising:
a plurality of memory mat rows each including a plurality of word drivers and a plurality of memory mats, each of the memory mats being arranged between associated adjacent two of the word drivers, each of the memory mats including a plurality of memory cells, the memory mats included in each of the memory mat rows being divided into a plurality of memory mat groups, each of the memory mat groups including at least four memory mats;
a first circuit configured to designate one of the memory mat rows as a selected memory mat row in response to a first part of row address information comprising a plurality of row address bits, the first part of the row address information including first plural ones of the row address bits, the first circuit being further configured to activate, in response to a second part of the row address information, adjacent two of the memory mats in each of the memory mat groups of the selected memory mat row with deactivating remaining two of the memory mats in each of the memory mat groups of the selected memory mat row, the second part of the row address information including second plural ones of the row address bits, the second plural ones of the row address bits being different from the first plural ones of the row address bits;
data terminals; and
a second circuit configured to respond to column address information and electrically connect one of the adjacent two of the memory mats in a first one of the memory mat groups in the selected memory mat row to the data terminal when the column address information takes a first address range and electrically connect one of the adjacent two of the memory mats in a second one of the memory mat groups in the selected memory mat row to the data terminal when the column address information takes a second address range.

12. The device as claimed in claim 11, wherein the first circuit is further configured to activate, in response to the second part of the row address information, one of the memory mats belonging to one of the memory mat groups of the selected memory mat row and one of the memory mats belonging to another of the memory mat groups of the selected memory mat row, that are adjacent to each other.

13. The device as claimed in claim 11, wherein the row address bits includes a more significant bit, a less significant bit and a plurality of intermediate significant bits between the more and less significant bits, the first plural ones of the row address bits comprising the intermediate significant bits, and the second plural ones of the row address bits comprising the more and less significant bits.

14. The device as claimed in claim 11, further comprising an additional data terminals, and the second circuit being further configured to respond to the column address information and electrically connect one of the adjacent two of the memory mats in a third one of the memory mat groups in the selected memory mat row to the additional data terminal when the column address information takes the first address range and electrically connect one of the adjacent two of the memory mats in a fourth one of the memory mat groups in the selected memory mat row to the additional data terminal when the column address information takes the second address range.

15. The device as claimed in claim 11, further comprising a plurality of sense amplifier arrays, each of the sense amplifier arrays being between associated adjacent two of the memory mat rows.
